(19) United States
(12) Patent Application Publication
(10) Pub. No.: US 2004/0007180 A1
(43) Pub. Date: Jan. 15, 2004

(54) Film-formation apparatus and source supplying apparatus therefor, gas concentration measuring method

(75) Inventors: Hideaki Yamasaki, Nirasaki-shi (JP); Yumiko Kawano, Nirasaki-shi (JP)

Correspondence Address: CROWELL & MORING LLP, INTELLECTUAL PROPERTY GROUP, P.O. BOX 14300, WASHINGTON, DC, 20044-4300, US

(73) Assignee: Tokyo Electron Limited, Minato-ku (JP)

(21) Appl. No.: 10/615,926

(22) Filed: Jul. 10, 2003

(30) Foreign Application Priority Data
Jul. 10, 2002 (JP) 2002-201532
Jul. 3, 2003 (JP) 2003-191044

(51) Int. Cl. C23C 16/00; G01N 7/00

(52) U.S. Cl. 118/715; 73/23.2

(57) ABSTRACT

A film-formation apparatus includes a film-formation chamber and a source gas supplying apparatus supplying a source gas to the film-formation chamber together with a carrier gas, wherein the source gas supplying apparatus includes a concentration detector detecting a concentration of the source gas and a gas flow controller controlling a flow rate of an inert gas added to the carrier gas based on a result of measurement of the concentration of the source gas obtained by the concentration detector.

### BACKGROUND OF THE INVENTION

The present invention generally relates to film-formation apparatuses, and more particularly to a CVD apparatus that can monitor and control the source gas concentration by way of an infrared spectrometer.

CVD is an indispensable film-formation technology in the fabrication process of semiconductor devices.

In the film-formation process according to CVD (chemical vapor deposition), particularly MOCVD (metal-organic chemical vapor deposition), in which formation of film is achieved by using an MO (metal-organic) source, a liquid source compound that contains the constituent elements of the film to be formed, or a liquid source prepared by dissolving a solid source compound containing such constituent elements into a solvent, is transported to a vaporizer located near to the processing vessel. There, the vaporizer causes vaporization of the source compound thus transported and there is produced a source gas as a result. The source gas thus produced is then introduced into a processing vessel of the CVD apparatus, and desired formation of a film such as an insulation film, a metal film or a semiconductor film, is achieved in the processing vessel, by causing decomposition of the source gas.

In the MOCVD process, on the other hand, there are cases in which a liquid source compound or a solid source compound has to be vaporized in a bubbler. In such a case, the source gas formed as a result of the bubbling is transported to the processing vessel via a source gas line. In such a case, there is a need of controlling the concentration of the source gas by controlling the flow rate or pressure of the source gas in the gas line for obtaining a film of desired quality.

In the case using a vaporizer, the vaporizer can be provided adjacent to the processing vessel or inside the processing vessel, and the concentration of the source gas supplied to the processing vessel can be controlled by merely controlling the amount of the liquid to be supplied to the vaporizer. There is no particular need of direct detection and monitoring of the concentration of the source gas supplied to the processing vessel.

In the case of supplying a source gas from a bubbler to the processing vessel via a source gas line, too, the concentration of the source gas supplied to the processing vessel has been easily adjusted by merely controlling the carrier gas flow rate or pressure. Thus, there has been no particular need of direct detection and monitoring of the source gas concentration supplied to the processing vessel in the conventional CVD technology.

In the case of forming high-K dielectric films or ferroelectric films, which are used in recent advanced semiconductor devices, or in the case of forming a tungsten (W) film or a ruthenium (Ru) film used also in these semiconductor devices, on the other hand, the vapor pressure of the source gas obtained from a source material is generally very low, and there can be a case in which the amount of the source gas sufficient for applying an ordinary source gas concentration control, which relies upon control of vaporization of the source gas, cannot be achieved by way of vaporization of the source material.

Thus, in the case of conducting a CVD process with such a low vapor pressure source material, a very small amount vapor produced by holding the source material at a predetermined temperature is supplied to the processing vessel as a source gas by using a carrier gas. Thereby, there occurs extensive dilution of the source gas by the carrier gas, and there arise a case in which accurate determination of the source gas concentration for the source gas actually introduced into the processing vessel is difficult.

Particularly, in the case of conducting a desired CVD process while using a solid source compound of low vapor pressure, there may occur a change of state of the source material with consumption of the source material. Such a change may occur, particularly with regard to the effective surface area of the source material contacting with the carrier gas. When such a change of surface area is caused in the source material, it is generally not possible to avoid significant fluctuation of source gas concentration. Further, such a solid source material has a tendency of forming a temperature distribution inside because of poor heat conduction, contrary to the case of using a liquid source material. This also contributes to the tendency of deviation of the source gas concentration from the proper concentration range.

Further, in the case of using a liquid source material, too, the fluctuation of the source gas concentration can provide profound effect on the process, as long as the vapor pressure of the source compound is low.

Thus, in such recent technology of MOCVD, direct detection of the source gas concentration is becoming a major issue.

As noted above, it is preferable to measure or monitor the source gas concentration directly when conducting a CVD process when such a low-vapor pressure compound is used for the source material. On the other hand, the conventional gas concentration measurement method, such as the one that uses acoustic emission (AE) or specific heat, has a drawback in that reliable measurement is not possible when the measurement is conducted under a low-pressure environment such as the pressure of 50 Torr (6660 Pa) or less. Thus, such a conventional measurement process of gas concentration is not applicable to the case of the CVD film-formation process conducted while using a low-vapor pressure source material such as the MOCVD process.

Meanwhile, there is proposed a film-formation apparatus disclosed in the Japanese Laid-Open Patent Publication 2001-234348 that is capable of measuring the source gas concentration directly by Fourier-transform infrared (FTIR) spectrometer. This prior art film formation apparatus also controls the gas flow rate based on the result of measurement of the source gas concentration.

In this conventional film-formation apparatus and method, the mixing ratio of plural gas species is measured by FTIR, and the mixing ratio is adjusted by controlling the carrier gas flow rate ratio based on the result of the measurement.

Thus, in the case of using FTIR, it is possible to detect a concentration ratio of the source gases directly even in a low-pressure environment as used in an MOCVD process. On the other hand, it is not always easy to correct the concentration of the source gases in such a process when it was found, as a result of the FTIR measurement, that the source gas concentration ratio is deviated from a proper concentration range.

More specifically, the foregoing prior art film-formation process compensates for the change of source gas concentration by increasing or decreasing the carrier gas flow rate when it was judged by the FTIR measurement that the source gas concentration is deviated from a proper concentration range.

In such a control scheme, there is a possibility that increase or decrease of the carrier gas flow rate invites, depending on the vaporization rate of the liquid or solid source material used and also on the carrier gas flow rate, an unpredictable change of source gas concentration for the source gas that is actually introduced into the processing vessel.

Consider now the case of increasing the carrier gas flow rate, under the situation that the source gas concentration in the carrier gas is judged as being smaller than the proper concentration range, such that the vaporization of the source material is facilitated and the concentration of the source gas supplied to the CVD film-formation chamber is increased as a result. There can be a case in which the vaporization of the source material cannot follow the increase of the carrier gas flow rate. When this is the case, the source gas produced from the source material is merely diluted by a large amount of the carrier gas, and the source gas concentration in the carrier gas is reduced, contrary to what is intended. Thereby, it becomes necessary to conduct a complex and time-consuming control process for recovering the desired source gas concentration.

In the case of decreasing the carrier gas flow rate under the situation in which the source gas concentration in the carrier gas is judged as being larger than the proper concentration range, so as to reduce the vaporization of the source material and decrease the concentration of the source gas introduced into the CVD chamber, the source gas vaporized from the source material is concentrated as a result of use of small amount of carrier gas. When this is the case, the source gas concentration in the carrier gas is increased, contrary to what is intended.

Further, while it is possible to control the source gas concentration by adjusting the temperature of the liquid or solid source material, such a procedure is not realistic for the exact and quick control of the source gas concentration in view of the fact that the vaporization rate changes drastically with the bottle temperature and in view of the fact that it requires a very rigorous temperature regulation for achieving the desired gas concentration. In addition, it should be noted that the response speed of the source gas temperature is generally slow even when the vaporization temperature itself can be changed quickly and exactly during the film-formation process. Thus, the use of such a process of controlling the vaporization temperature is not realistic in the situation in which there is a demand of quick and exact adjustment of the source gas concentration.

### SUMMARY OF THE INVENTION

Accordingly, it is a general object of the present invention to provide a novel and useful film-formation apparatus wherein the foregoing problems are eliminated.

Another and more specific object of the present invention is to provide a CVD apparatus as well as a source gas supplying apparatus used therefor, wherein the concentration of a source gas supplied to a processing vessel of the CVD apparatus together with a carrier gas for conducting a CVD process is adjusted with high precision and with high speed even when the CVD process is conducted by using a low vapor pressure source material.

Another object of the present invention is to provide a film-formation apparatus, comprising:

a film-formation chamber; and

a source gas supplying apparatus supplying a source gas to said film-formation chamber together with a carrier gas,

said source gas supplying apparatus comprising:

a detector detecting a concentration of said source gas; and

a gas flow controller controlling a flow rate of an inert gas added to said carrier gas based on a result of measurement of said concentration of said source gas obtained by said detector.

According to the present invention, it becomes possible to supply the source gas always with a proper concentration at the time of film formation process, by controlling the concentration of the source gas before or during the film-formation process. As a result, it becomes possible to conduct the film formation process with excellent film quality, reliability and reproducibility. As the source gas is adjusted to have the proper concentration in the state the inert gas is added thereto, any deviation from the proper concentration can be immediately corrected by merely increasing the flow rate of the inert gas, as in the case of when it is judged that the measured concentration of the source gas has exceeded the upper limit of the proper compositional range. In the event the measured concentration of the source gas has decreased below the lower limit of the proper concentration range, on the other hand, the proper concentration is restored by merely decreasing the flow rate of the inert gas.

It should be noted that this inert gas functions as a diluting gas, and the present invention controls the flow rate of this diluting gas based on the source gas concentration measured by the detector with reference to the predetermined proper concentration range. This adjustment of the source gas concentration by way of control of the inert gas added to the source gas is predictable and can be achieved with high precision and high speed, in contrast to the case of attempting such an adjustment by way of controlling the carrier gas flow rate.

It should be noted that the concentration of the source gas is measured in the state the inert gas is added thereto in the present invention. In other words, the concentration of the source gas is measured in the state it is introduced into the CVD apparatus for film formation. By measuring the concentration of the source gas in the flow passage that is connected to the processing chamber of a CVD apparatus, and particularly by measuring the concentration of the gas directly, a direct and reliable control of the source gas concentration becomes possible.

By using a Fourier transform infrared spectrometer or a non-dispersion type infrared spectrometer, which shows high precision and high sensitivity also under a low-pressure environment as the means of the measurement of the source gas concentration, it becomes possible to control the film formation process that uses a low vapor pressure source material such as a solid source material effectively. As noted before, there is a tendency that the source gas flow rate fluctuates significantly in the case a solid source material is used.

Another object of the present invention is to provide a film-formation apparatus, comprising:

a film-formation chamber; and

a source gas supplying apparatus supplying a source gas to said film-formation chamber together with a carrier gas via a gas passage in the form of a mixed gas,

said source supplying apparatus comprising:

a gas concentration measurement part measuring the concentration of said source gas contained in said mixed gas in said gas passage;

a gas concentration controller connected to said gas passage, said gas concentration controller adding an inert gas to said mixed gas in said gas passage; and

an inert-gas flow-rate controller controlling the flow rate of said inert gas added by said gas concentration controller based on a measured concentration of said source gas obtained by said gas concentration measurement part,

said gas concentration measurement part including a manometer for measuring the pressure of said mixed gas in said gas passage, said gas concentration measurement part correcting said measured concentration of said source gas based on a pressure measured by said manometer.

Another object of the present invention is to provide a gas concentration detection method, comprising the steps of:

supplying a mixed gas containing therein a source gas to a flow passage;

measuring the pressure of said mixed gas in said flow passage;

injecting infrared light to said mixed gas in said flow passage;

acquiring an absorption spectrum of said source gas by detecting said infrared light after said infrared light has passed through said mixed gas in said flow passage;

acquiring the concentration of said source gas in said mixed gas by correcting an intensity of said absorption spectrum, said step of correction comprising the step of applying a correction term including therein said pressure.

According to the present invention, it becomes possible to obtain the absolute value of the source gas concentration by injecting a signal into the mixed gas that contains therein the source gas, detecting the signal after it has passed through the mixed gas, and correcting the detected signal by using a correction factor that contains therein the term of total pressure of the mixed gas.

Other objects and further features of the present invention will become apparent from the following detailed description when read in conjunction with the attached drawings.

### BRIEF DESCRIPTION OF THE DRAWINGS

FIG. 1 is a diagram showing the construction of a processing vessel of an MOCVD apparatus used in the present invention;

FIG. 2 is a diagram showing the construction of an MOCVD apparatus according to a first embodiment of the present invention;

FIG. 3 is a diagram showing the construction of an MOCVD apparatus according to a second embodiment of the present invention;

FIG. 4 is a diagram showing the construction of an MOCVD apparatus according to a third embodiment of the present invention;

FIG. 5 is a diagram showing the construction of an MOCVD apparatus according to a fourth embodiment of the present invention;

FIG. 6 is a flowchart showing an example of processing for controlling a source gas concentration in a mixed gas according to any of the first through fourth embodiment;

FIG. 7 is a diagram showing an example of an FTIR spectrum obtained for W(CO)₆;

FIG. 8 is a diagram showing the construction of an MOCVD apparatus according to a fifth embodiment of the present invention;

FIG. 9 is a diagram showing the construction of an MOCVD apparatus according to a modification of the MOCVD apparatus of FIG. 8;

FIG. 10 is a diagram showing the construction of an MOCVD apparatus according to another modification of the MOCVD apparatus of FIG. 8;

FIG. 11 is a diagram showing the construction of an MOCVD apparatus according to a further modification of the MOCVD apparatus of FIG. 8;

FIG. 12 is a diagram showing the construction of an MOCVD apparatus according to a further modification of the MOCVD apparatus of FIG. 8;

FIG. 13 is an MOCVD apparatus according to a further modification of the MOCVD apparatus of FIG. 8;

FIG. 14 is a diagram showing the construction of an FTIR apparatus according to a sixth embodiment of the present invention;

FIG. 15 is a diagram showing the construction of a non-dispersion infrared spectrometer according to the sixth embodiment of the present invention; and

FIG. 16 is a diagram showing a further modification of the MOCVD apparatus of FIG. 12

### DETAILED DESCRIPTION OF THE PREFERRED EMBODIMENTS

[First Embodiment]

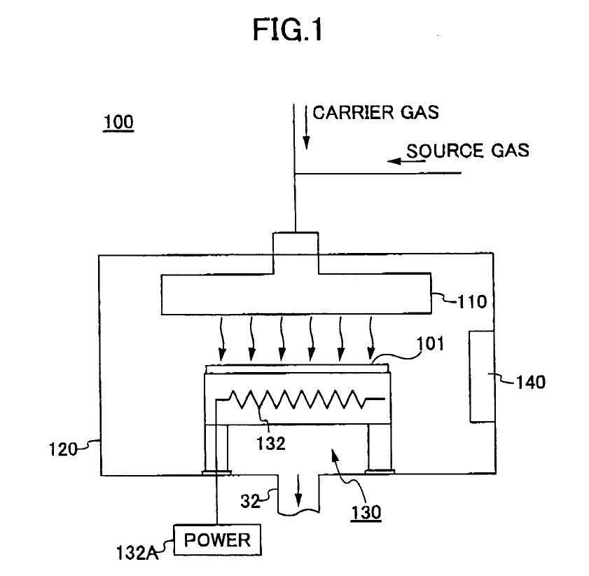

FIG. 1 shows the construction of a processing vessel 100 used in a first embodiment of the present invention in a cross-sectional view.

Referring to FIG. 1, the processing vessel 100 includes a processing vessel body 120 and a stage 130 provided in the processing vessel body 120 for supporting a semiconductor wafer 101, wherein the stage 130 is embedded with a heating element 132 driven by a power source 132A, and there is provided a shower head 110 inside the processing vessel body 120 so as to face the stage 130. The showerhead 110 introduces a gas supplied from a source gas line 30 into the process space inside the processing vessel body 120.

Further, there is provided a gate valve 140 at the sidewall of the processing vessel body 120 for loading and unloading the semiconductor wafer 101 to and from the processing vessel body 120. The processing vessel body 120 is evacuated via an evacuation line 32.

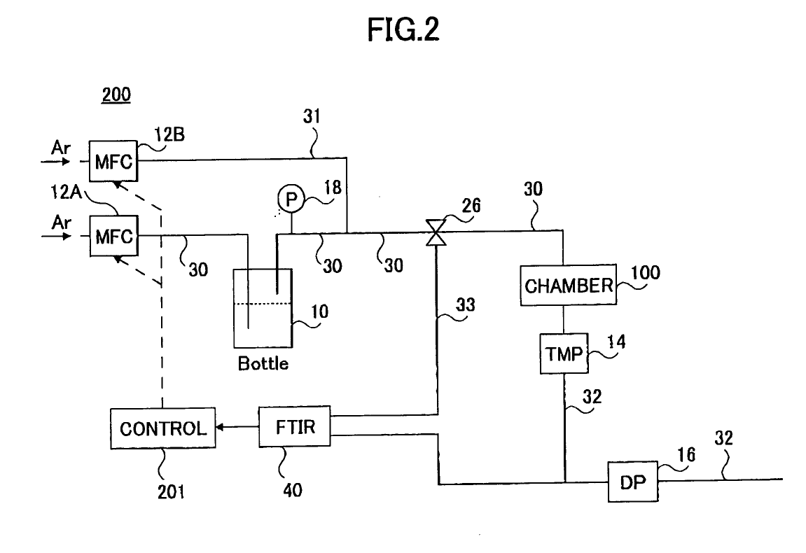

FIG. 2 shows the construction of an MOCVD apparatus 200 that uses the processing vessel 100 of FIG. 1 schematically.

Referring to FIG. 2, the MOCVD apparatus 200 includes a source bottle 10, wherein the source bottle 10 is supplied with an inert gas such as Ar, Kr, N₂, H₂, and the like, from a source gas line 30 via a mass flow controller (MFC) 12A, which is provided in a part of the source gas line 30. Thereby, the mass-flow controller 12A controls the flow rate of the inert gas supplied to the source bottle 10.

The source bottle 10 accommodates therein a liquid or solid source material and produces a source gas therein as a result of vaporization of the source material. The inert gas thus supplied to the source bottle 10 functions as a carrier gas and transports the source gas from the source bottle 10 to the processing vessel 100. Thereby, the source gas flows out from the source bottle 10 at the outlet port thereof and is transported along the source gas line 30. It should be noted that there is provided a manometer 18 in the vicinity of the outlet port of the source bottle 10 for detecting the pressure inside the source bottle 10.

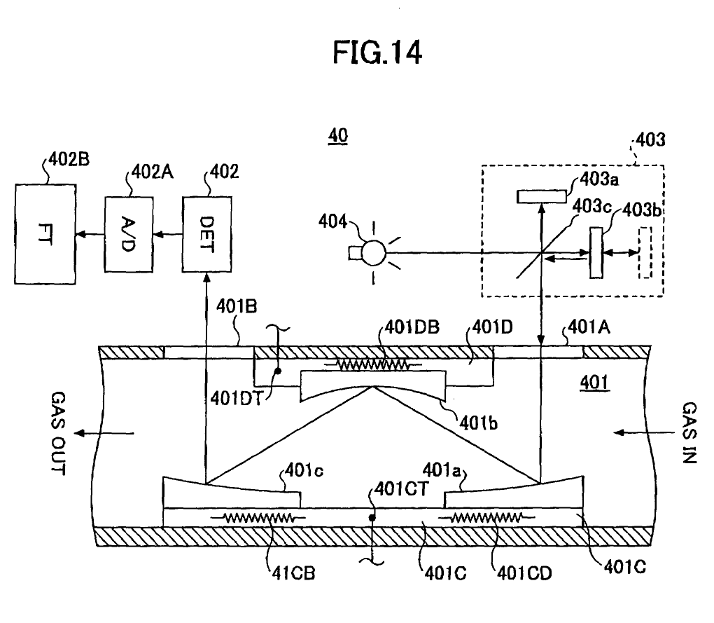

In the MOCVD apparatus 200 of FIG. 14, it should further be noted that there is provided a diluting gas line 31 to the source gas line 30 so as to merge at a downstream side of the manometer 18, and an inert gas such as Ar, Kr, N₂, H₂, and the like, is supplied to the diluting gas line 31 via another mass-flow controller 12B. It should be noted that the mass-flow controller 12B controls the flow rate of the inert gas added to the source gas line 30.

It should be noted that this inert gas in the diluting gas line 31 functions as a diluting gas when it is added to the source gas line 30 and dilutes the source gas transported through the source gas line 30 from the source bottle 10. Hereinafter, the gas in the source gas line 30 thus diluted by the inert gas in the gas line 31 will be referred to as a “mixed gas”. This mixed gas is supplied to the processing vessel 100 through the source gas line 30.

In the construction of FIG. 2, a turbo molecular pump (TMP) 14 is provided to the evacuation line 32 connected to the processing vessel 100, and there is further provided a dry pump (DP) behind the turbo molecular pump 14 for boosting the same. By driving these pumps 14 and 16, the interior of the processing vessel body 120 is maintained at a predetermined pressure. For example, the turbo molecular pump 14 can evacuate the process space inside the processing vessel 120 to a high-degree vacuum state characterized by the pressure of about 1 Torr (133 Pa). Thereby, it becomes possible to conduct the film formation process that uses a source material of low vapor pressure.

It should be noted that there is provided a pre-flow line 33 in the source gas line 30 so as to bypass the processing vessel 100 at the downstream side of the source bottle 10, and the mixed gas in the source gas line 30 is supplied selectively to one of the pre-flow line 33 or to the source gas line 30 connected to the processing vessel 100 by the switching of a valve 26 provided on the source gas line 30 from the source bottle 10. The pre-flow line 33 is provided for stabilizing the flow rate of the mixed gas supplied to the processing vessel 100 at the time of the film-formation process and to pre-adjust the concentration of the mixed gas. Thus, the mixed gas is caused to flow through the pre-flow line 33 in advance to each step of processing the substrate 101.

Meanwhile, the mixed gas supplied to the processing vessel 100 has to contain the source gas with a proper concentration range in order to achieve the desired film formation. Further, the mixed gas is required to contain the source gas with a constant concentration within the proper concentration range in order to avoid variation of film quality in each film-formation step when the film-formation step is conducted repeatedly.

In the MOCVD apparatus 200 of FIG. 2, on the other hand, there arises a difficulty of detecting the source gas concentration accurately because of the fact that the carrier gas and also the diluting gas are added to the source gas when supplying the source gas to the processing vessel 100, contrary to the case of supplying the source gas directly from a vaporizer. As noted previously, the concentration of the source gas tends to change with the pressure variation or variation of the surface area of the source material, particularly when a solid source material is used, and it is difficult stabilize the concentration of the source gas in the mixed gas.

Thus, according to a first embodiment of the present invention, variation of the source gas concentration in the mixed gas is detected with high precision by using a Fourier-transform infrared spectrometer, and the flow rate of the inert gas is controlled by using the mass-flow controller 12B and/or 12A such that the source gas concentration in the mixed gas falls always in a predetermined, proper concentration range.

More specifically, the present embodiment provides a Fourier-transform infrared spectrometer 40 referred to hereinafter as FTIR 40 in the pre-flow line 33 of the MOCVD apparatus 200, wherein the FTIR 40 includes a wave monitor using a laser light and a movable mirror. More specifically, the FTIR 40 includes an interferometer, infrared detector and a processing unit and measures the concentration of gas species contained in a gas based upon the absorption spectrum of respective gas species, by irradiating an infrared beam upon the gas via an interferometer and processing the output of the infrared detector by the processing unit.

The pre-flow line 33 is merged to the evacuation line 32 at the upstream side of the dry pump 16 and is set to the predetermined degree of vacuum by the dry pump 16. In the MOCVD apparatus 200 of FIG. 2, it becomes possible to measure the source gas concentration under the pressure of 50 Torr (6660 Pa) or less, in which concentration measurement by way of acoustic emission process is not possible, by providing the FTIR 40 in the pre-flow line 33.

In the present embodiment, it should be noted that the FTIR 40 provided in the pre-flow line 33 measures the source gas concentration in the mixed gas (referred to hereinafter as “measured concentration”) and supplies a signal indicative of the measured concentration to a controller 201.

Thus, in the event it is judged in the controller 201 that the measured concentration change has exceeded a predetermined range, the controller 201 controls the mass-flow controller 12B and/or 12A, and increases or decreases the flow rate of the inert gas. It should be noted that this controller 201 may be provided inside the FTIR 40 or inside any of the mass-flow controller 12B and/or 12A.

According to the first embodiment of the present invention, the source gas concentration in the mixed gas is controlled constant before conducting a film formation step for each substrate, and the source gas is introduced into the processing vessel with controlled concentration in each film-formation process. Thereby, wafer-to-wafer variation of film quality is successfully minimized.

Because the source gas concentration is adjusted to the proper concentration range at the beginning of the process by adding the diluting gas to the carrier gas, it is possible to increase the source gas concentration immediately, in the event the source gas concentration has decreased during the film-formation process as a result of decrease of the source material or as a result of decrease of vaporization efficiency of the source material, and the like, by decreasing the flow rate of the diluting gas. Similarly, it is possible to decrease the source gas concentration immediately in the event the source gas concentration has increased during the film-formation process, by increasing the flow rate of the diluting gas.

As explained before, increase of the carrier gas flow rate does not always lead to increase of source gas concentration. This is particularly true in the case of using a solid source material, in which there is caused a reduction of surface area with the progress of the film-formation process. In such a case, the efficiency of vaporization decreases when the carrier gas flow rate is increased.

In the present invention, on the other hand, it is possible to increase the source gas concentration by merely decreasing the flow rate of the diluting gas. Of course, it is possible to change the carrier gas flow rate simultaneously to the change of the diluting gas flow rate.

As the diluting gas does not contain the source gas, it is easy to determine the amount of the flow rate change from the measured concentration obtained by FTIR and from the predetermined proper concentration range. Thus, the concentration control of the source gas by the increase or decrease of the diluting gas can be conducted at high speed with high precision, contrary to the case of conducting the concentration control by way of control of the carrier gas alone.

[Second Embodiment]

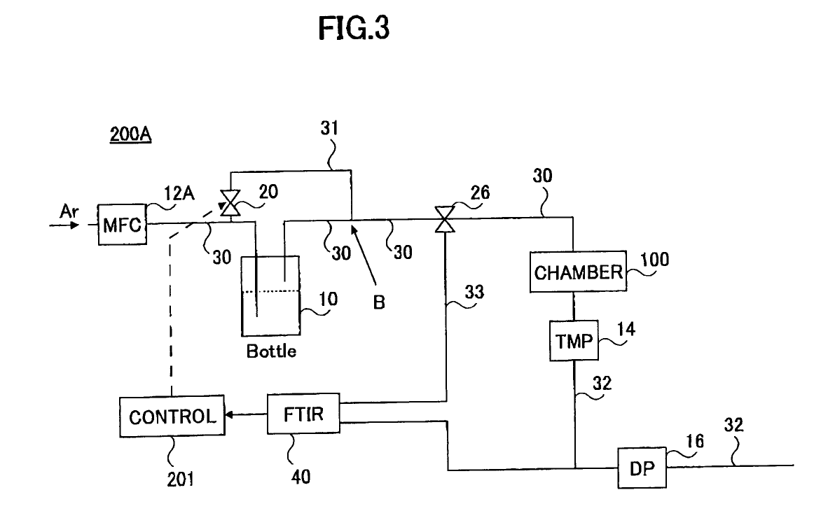

FIG. 3 shows the construction of an MOCVD apparatus 200A according to a second embodiment of the present invention, wherein those parts corresponding to the parts described previously are designated by the same reference numerals and the description thereof will be omitted.

Referring to FIG. 3, it can be seen that the inert gas such as Ar, Kr, N₂, H₂, and the like, is supplied to the source bottle 10 via the source gas line 30 via the mass-flow controller 12A, wherein the mass-flow controller 12A controls the flow rate of the inert gas to be supplied to the source bottle 10. The source bottle 10 accommodates therein a liquid or solid source used for the film-formation process. Thereby, the source gas is produced as a result of the vaporization of the source material in the source bottle 10. The inert gas thus supplied to the source bottle 10 is forwarded to the source gas line 30 from the outlet port of the source bottle 10 as the carrier gas.

According to the second embodiment of the present invention, it can be seen that the diluting gas line 31 is provided to the source gas line 30 at the downstream side of the mass-flow controller 12A so as to bypass the source bottle 10, and the diluting gas line 31 is provided with the inert gas diverted from the source gas line 30. This inert gas is admixed to the carrier gas carrying the source gas from the source bottle 10 upon merging to the source gas line at the node B as the diluting gas, and the mixed gas formed of the source gas, carrier gas and the diluting gas is caused to flow through the source gas line 30 at the downstream side of the node B. Thereby, the source gas in the mixed gas is diluted by the inert diluting gas in the gas line 31. The flow rate of this diluting gas is controlled by a valve 20 provided in the gas line 31.

This mixed gas is then supplied selectively to one of the processing vessel 100 or the pre-flow line 33 in which the FTIR 40 is provided, after passing through the source gas line 30.

The FTIR 40 of the pre-flow line 33 measures the source concentration in the mixed gas and supplies an output signal indicative of the measured concentration to the controller 201. Thus, the controller 201 judges whether the measured concentration falls within the predetermined proper concentration range or not and conducts the control of increasing or decreasing the diluting gas flow rage by controlling the valve 20 when it is judged that the measured concentration deviated beyond the proper concentration range.

According to the second embodiment of the present invention, it becomes possible to minimize the wafer-to-wafer variation of the film quality by monitoring the source gas concentration by using the FTIR 40 provided in the pre-flow line 33, similarly to the first embodiment. Further, the present embodiment, which uses FTIR for the concentration measurement, is suitable for the film-formation process that uses the source material of low vapor pressure. Further, any deviation of the source gas concentration in the mixed gas beyond the proper concentration range is corrected immediately by increasing or decreasing the flow rate of the diluting gas.

In the present embodiment in which the flow rate of the diluting gas is controlled by the valve 20 provided in the diluting gas line 31, it is possible to adjust the flow rate of the diluting gas and the carrier gas by using the single mass-flow controller 12A. Further, the construction of the present embodiment, in which the diluting gas line 31 is branched from the line 30 and merged thereto again, has the feature that the inert gas flow rate before branching becomes generally equal to the inert gas flow rate at the merging node B. Thus, it becomes possible to maintain a constant flow rate for the mixed gas supplied to the processing vessel 100 while controlling the source gas concentration therein by way of increasing or decreasing the diluting gas flow rate. As a result, wafer-to-wafer variation of film quality is reduced further by using the present embodiment.

[Third Embodiment]

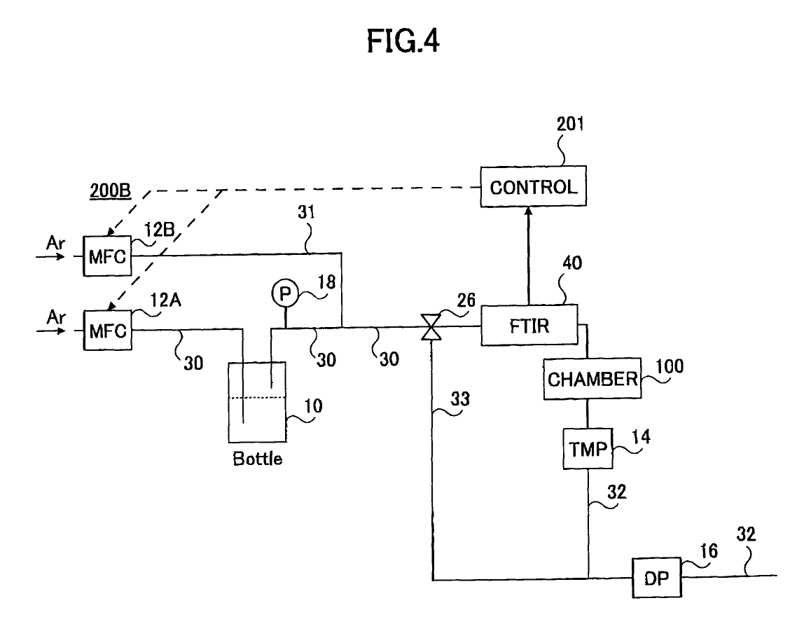

FIG. 4 shows the construction of an MOCVD apparatus 200B according to a third embodiment of the present invention, wherein those parts corresponding to the parts described previously are designated by the same reference numerals and the description thereof will be omitted.

Referring to FIG. 4, it can be seen that the inert gas such as Ar, Kr, N₂, H₂, and the like, is supplied to the source bottle 10 from the mass-flow controller 12A through the source gas line 30, wherein the mass-flow controller 12A controls the flow rate of the inert gas supplied to the source bottle 10. The source bottle 10 accommodates therein a liquid or solid source material used for film-formation, and the source material undergoes vaporization in the source bottle 10. The inert gas thus supplied to the source bottle 10 functions as a carrier gas and carries the source gas therewith. Further, the manometer 18 is provided in the vicinity of the gas outlet of the source bottle 10 for detecting the pressure in the source bottle 10.

The source gas line 30 is further provided with the diluting gas line 31 such that the diluting gas line 31 merges at the downstream side of the manometer 18, and the diluting gas line 31 is supplied with an inert gas such as Ar, Kr, N₂, H₂, and the like, via the mass-flow controller 12B. Thereby, mass-flow controller 12B controls the flow rate of the inert gas to be merged to the source gas line 30. It should be noted that this inert gas is admixed to the source gas and the carrier gas from the source bottle 10 upon merging to the source gas line 30, and the mixed gas is formed in the source gas line 30 as a result of the admixing. Thereby, the inert gas thus added causes dilution of the source gas contained in the mixed gas. The mixed gas thus formed is then supplied to the processing vessel 100 through the source gas line 30. In the present embodiment, it is also possible to construct the diluting gas line 31 similar to the one explained with reference to the second embodiment.

In the present embodiment, the evacuation line 32 for evacuating the processing vessel 100 is provided with the turbo molecular pump 14, and the turbo molecular pump 14 is boosted by the dry pump 16 provided at the downstream side of the turbo molecular pump 14. Thereby, the process space in the processing vessel 100 is maintained at a predetermined pressure or predetermined degree of vacuum such as 1 Torr (133 Pa) or less. Such a low pressure environment is particularly important in the film-formation process that uses a low vapor pressure source material.

It should be noted that the source gas line 30 is provided with the pre-flow line 33 such that the pre-flow line 22 bypasses the processing vessel 100, wherein the pre-flow line 33 is supplied with the mixed gas in the source gas line 30. Thereby, the mixed gas is supplied selectively to one of the pre-flow line 33 and the source gas line 30 connected to the processing vessel 100 by the activation of the valve 26 Here, the pre-flow line 33 is provided for stabilizing the flow rage of the mixed gas supplied to the processing vessel 100 at the time of the film-formation process and to adjust the concentration of the mixed gas in advance. As can be seen, this pre-flow line 33 merges to the evacuation line 32 at the upstream side of the dry pump 16. Thus, the pressure inside the pre-flow line 33 is determined by the dry pump 16.

In the first and second embodiments described before, it should be noted that the concentration of the mixed gas supplied to the processing vessel 100 is monitored by the FTIR 40 provided in the pre-flow line 33. In the case of switching the mixed gas hitherto supplied to the pre-flow line 33, to the source gas line 30 connected to the processing vessel in the gas supply system having such a construction, there can be a case that the source gas concentration undergoes a change before and after the switching as a result of different diameter of the gas lines or existence or non-existence of the processing vessel body 120 in the evacuation path, which causes a change of impedance in the evacuation system, and such a change of impedance of the evacuation system can cause a change of pressure in the source bottle 10. In the case of conducting film-formation by using a low vapor pressure source, in particular, the pressure inside the source bottle 10 is held at the pressure of 1 Torr (133 Pa) or less because of the use of the turbo molecular pump 14 for facilitating the vaporization of the source material in the source bottle 10. On the other hand, the pre-flow line 33 is evacuated by the dry pump 16 alone, and thus, it is difficult to realize such a low pressure in the pre-flow line 33.

Even in such a case, the first and second embodiments can successfully reduce the wafer-to-wafer variation of film quality by maintaining the source gas concentration in the mixed gas flowing through the pre-flow line 22 before each film-formation step.

However, it would be more advantageous when a direct control of the source gas concentration in the mixed gas supplied actually to the processing vessel is achieved. Thereby, it should be noted that such a direct control of the source gas concentration in the mixed gas actually supplied to the processing vessel 100 has to be conducted in a short time period in view of the fact that the film-formation process is in progress in the processing vessel 100 while using this mixed gas.

The present invention can immediately correct any deviation of the source gas concentration by way of increase of decrease of the diluting gas, and thus, it becomes possible to control the source gas concentration in the mixed gas supplied directly to the processing vessel 100.

More specifically, the present embodiment provides the FTIR 40 in the source gas line 30 connected to the processing vessel 100 for measuring the source gas concentration of the mixed gas introduced into the processing vessel 100. It should be noted that this source gas line 30 may be held at a low pressure such as 1 Torr (133 Pa) or less by using the turbo molecular pump 14 and the dry pump 16 in order to facilitate vaporization of the low vapor pressure source material. Even in such a case, the source gas concentration is measured accurately by using the FTIR 40.

In the present embodiment, the FTIR 40 provided in the source supply line 30 connected to the processing vessel 100 measures the source gas concentration in the mixed gas and supplied an output signal indicative of the measured concentration to the controller 201. When the controller 201 judges that the measured concentration of the FTIR 40 has exceeded the proper concentration range, the controller 201 controls the mass-flow controller 12B and/or 12A and the flow rate of the inert gas added to the mixed gas is increased or decreased.

According to the fourth embodiment of the present invention, it becomes possible to immediately correct any deviation of the source gas concentration in the mixed gas from the proper concentration range by increasing or decreasing the diluting gas flow rate similarly to the previous embodiments.

Thus, the present embodiment enables direct measurement of the source gas concentration in the mixed gas, which is actually used for film formation, by using the FTIR 40 provided in the source gas line 40 connected to the processing vessel 100. Thereby, any deviation of the source gas concentration in the mixed gas currently in use in an on-going film formation process is detected and corrected immediately. Thereby, the film-formation processing can be conducted by using a source gas of which concentration is always controlled to the proper compositional range, and the desired film quality is maintained over the repeatedly conducted wafer-to-wafer film-formation processes.

[Fourth Embodiment]

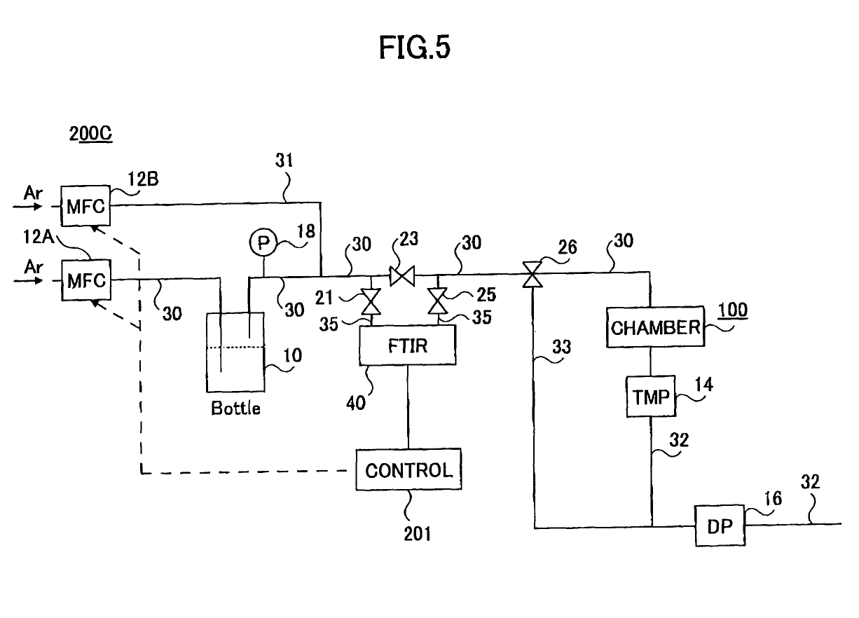

FIG. 5 shows the construction of an MOCVD apparatus 200C according to a fourth embodiment of the present invention, wherein those parts corresponding to the parts described previously are designated by the same reference numerals and the description thereof will be omitted.

Referring to FIG. 5, the inert gas such as Ar, Kr, N₂, H₂, and the like, is supplied to the source bottle 10 from the mass-flow controller 12A through the source gas line 30, wherein the mass-flow controller 12A controls the flow rate of the inert gas supplied to the source bottle 10. The source bottle 10 accommodates therein a liquid or solid source material used for the film-formation process, and the source gas is produced as a result of vaporization conducted in the source bottle 10. Thereby, the inert gas supplied to the source bottle 10 functions as a carrier gas and carries the vaporized source gas therewith. Further, the manometer 18 is provided in the vicinity of the outlet port of the source bottle 10 connected to the source gas line 30 for detecting the pressure inside the source bottle 10.

Further, there is provided the diluting gas line 31 such that the diluting gas line 31 merges the source gas line 30 at the downstream side of the manometer 18, and the inert gas such as Ar, Kr, N₂, H₂, and the like, is supplied to the diluting gas line 31 via the mass-flow controller 12B. Thereby, the mass-flow controller 12B controls the flow rate of the inert gas added to the source gas supply line 30. It should be noted that this inert gas is added, upon merging to the source gas line 30, to the source gas and the carrier gas from the source bottle 10 as a diluting gas, and there is formed a mixed gas in the source gas line 30 as a result of the mixing of the source gas, carrier gas and the diluting gas at the downstream side of the node where the gas line 31 merges the gas line 30. This mixed gas is then supplied to the processing vessel 100 along the source gas supply line 30. Here, it is possible to construct the diluting gas line 31 and the source gas supply line 30 similarly to the second embodiment.

The source gas supply line 30 is provided with the pre-flow line 33 so as to bypass the processing vessel 100 at the downstream side of the source bottle 10, and the pre-flow line 33 is supplied with the mixed gas from the source gas line 30. The mixed gas is thereby supplied selectively to one of the pre-flow line 33 and the source gas line 30 connected to the processing vessel 100 by the activation of the valve 26. It should be noted that this pre-flow line 33 is provided so as to stabilize the flow rate of the mixed gas supplied to the processing vessel 100 at the time of the film formation process and further to adjust the mixed gas concentration in advance. The pre-flow line 33 is connected to the evacuation line 32 at the upstream side of the dry pump 16. Thus, the pre-flow line 33 is evacuated to a predetermined pressure or degree of vacuum by the dry pump 16.

According to the fourth embodiment of the present invention, the FTIR 40 is provided at the downstream side of the node where the gas line 31 merges the gas line 30 but at the upstream side of the node where the pre-flow line 33 branches from the gas line 30, so as to enable measurement of the source gas concentration in the mixed gas introduced into the processing vessel 100 and so as to enable measurement of the source gas concentration in the mixed gas flowing through the pre-flow line 33.

As shown in FIG. 5, the FTIR 40 may be provided in a bypass line 35 bypassing from the source gas line 30. The bypass line 35 is provided with valves 21 and 25, and there is further provided a valve 23 in the source gas line 30 between the node where the bypass line 35 branches from the source gas line 30 and the node where the bypass line 35 merges the source gas line 30.

As a result of opening and closing of these valves 21, 23 and 25, the mixed gas is supplied selectively to either the bypass line 35 or the source gas line 30. Thus, the mixed gas is supplied to the bypass line 35 the source gas concentration is to be measured. When there is no need of measurement of the source gas concentration, the source gas is supplied directly to the downstream part of the source gas line 30.

The output of the FTIR 40 is supplied to the controller 201, and the controller 201 controls the mass-flow controller 12A and/or 12B in response to the output signal of the FTIR 40.

According to the fourth embodiment described above, it is possible to correct any deviation of the source gas concentration in the mixed gas beyond a predetermined proper concentration range immediately by increasing or decreasing the flow rate of the diluting gas.

As the FTIR 40 is disposed so as to measure both the source gas concentration introduced into the processing vessel and the source gas concentration in the pre-flow line 33, the present embodiment can control not only the source gas concentration before the commencement of the film-formation process but also the source gas concentration actually used for the film-formation process. In other words, the present embodiment enables monitoring of the source gas concentration of the mixed gas actually in use for the film formation process and correction of any deviation of the source gas concentration beyond the predetermined concentration range immediately. As the mixed gas used for the actual film-formation process has the source gas concentration already adjusted during the period in which the mixed gas is caused to flow through the pre-flow line, there can occur no large deviation in the source gas concentration when the mixed gas is switched and introduced into the processing vessel 100. Thus, the need of large change of the source gas concentration during the film-formation process by significantly increasing or decreasing the diluting gas is avoided, and a stable film formation becomes possible.

While the present invention has been described for the case of conducting film-formation process by using a single gas source specie, the present invention is applicable also to the case of conducting film-formation processing by using two or more gas species. In such a case, two or more source gas lines are provided for supplying the respective source gases to the CVD apparatus. Otherwise, the CVD apparatus has a construction similar to those described before.

It should be noted that the pre-flow line 33 is indicated as merging to the evacuation lien 32 at the upstream side of the dry pump 16. In such a case, there is a possibility that the source gas concentration is measured in the state in which the pressure of the mixed gas is higher than the case in which the mixed gas actually flows to the processing vessel 100. In order to avoid this problem and to measure the source gas concentration at the pressure in which the mixed gas is actually supplied to the processing vessel 100, it is possible to increase the diameter of the pipe of the pre-flow line 33 for the part extending from the outlet of the FTIR to the node where the pre-flow line 33 merges the evacuation line 32 at the upstream side of the dry pump 16. Alternatively, it is possible to merge the pre-flow line 33 to the evacuation line 32 not at the upstream side of the dry pump 16 but at the upstream side of the turbo molecular pump 14. Thereby, it is possible to provide a pressure regulation valve not illustrated in the pre-flow line 33 at the upstream side of the node where the pre-flow line 33 merges the evacuation line 32 and control the cell pressure to the pressure of the film-formation process when the FTIR 40 is activated to conduct the measurement of the source gas concentration.

Next, the control operation of the controller 201 in the various embodiments described heretofore will be explained.

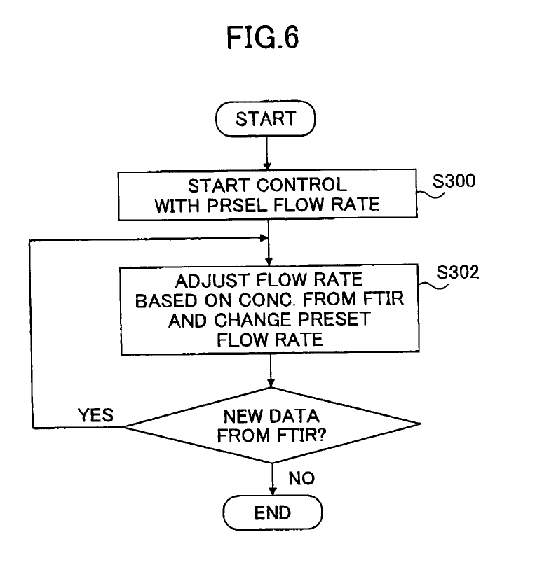

FIG. 6 shows an embodiment of control routine for controlling the source gas concentration in the mixed gas. While the illustration is omitted, this controller 201 is formed of a microcomputer including a CPU as a major component and stores the target source gas concentration C1 of the mixed gas, initial designed flow rate value Q1 of the diluting gas, the initial designed flow rate value Q2 of the carrier gas, and the like, in a memory.

In the step S300, the microcomputer sets the flow rate of the diluting gas to the value Q1 based on the data stored in the memory and produces a control signal setting the carrier gas flow rate to the value Q2. This control signal is then supplied to the mass-flow controllers 12A and 12B.

Next, in the step 302, the microcomputer determines the flow rate of the diluting gas and the flow rate of the carrier gas in response to the measured concentration C2 supplied from the FTIR 40 and determines the flow rate of the diluting gas and the flow rate of the carrier gas such that the measured concentration C2 coincides with the target concentration C1. Alternatively, the microcomputer decides whether or not the measured concentration C2 is deviated from the target concentration C1 beyond the allowable range. In this case, the microcomputer determines the flow rate of the diluting gas and the flow rate of the carrier gas such that the measured concentration C2 falls in the allowable range only when it is judges that the measured concentration C2 has deviated beyond the foregoing allowable range.

In the present embodiment, the overall flow rate of the diluting gas and the carrier gas is set constant before and after the adjustment. Thus, the flow rate of the diluting gas after the adjustment can be represented as Q1′=Q1+β and the flow rate of the carrier gas after the adjustment can be represented as Q2′=Q2−β. In the adjustment, the parameter β is determined.

Thus, in the initial routine step 302, the term −Q2/10 or +Q2/10 is substituted into the parameter β and the initial values Q1 and Q2 are updated to Q1′ and Q2′. The values thus updated are stored in the memory, and the corresponding control signals are transmitted to the mass-flow controllers 12A and 12B. Further, the step 302 is repeated in response to the input from the FTIR 40.

In the step 302 of the next routine, a new parameter β is determined in such a manner that the difference between the newly measured concentration C2 and the target concentration C1 is decreased and such that the newly determined parameter β has a smaller magnitude. By using the newly determined parameter β, the initial values Q1 and Q2 are updated to Q1′ and Q2′ and stored in the memory. Thereby, the corresponding control signals are transmitted to the mass-flow controllers 12A and 12B.

### EXAMPLE 1

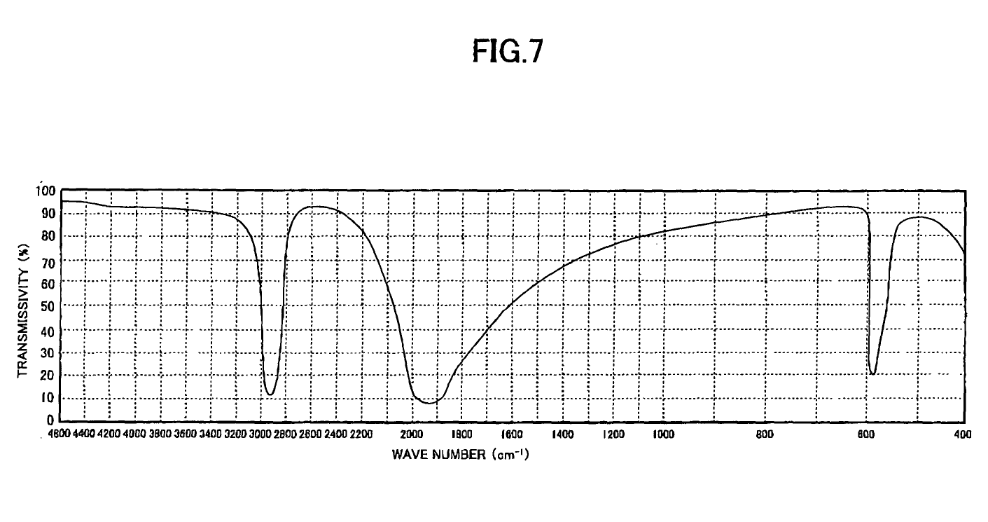

FIG. 7 shows an example of the infrared absorption spectrum of the metal organic gas W(CO)₆ (hexacarbonyl tungsten), wherein the horizontal axis represents the wavenumber while the vertical axis represents the transmissivity.

From FIG. 7, it can be seen that there exits characteristic absorption of carbonyl group (═CO) in the metal organic gas W(CO)₆ at the wavenumers of about 2900 cm⁻¹, 1900 cm−1 and 500 cm⁻¹.

In order to confirm the sensitivity of the FTIR 40 for the concentration change of the W(CO)₆ gas, an experiment was made in which the source bottle 10 is held at the temperatures of 25° C., 45° C. and 60° C. and an Ar carrier gas is supplied with the flow rate of 50 SCCM. Thereby, the FTIR 40 was provided not in the pre-flow line 33 but at the upstream side of the processing vessel 100 as in the case of the third embodiment. Here, the pressure of the FTIR cell becomes 80 Pa, 85 Pa and 87 Pa, respectively, and it was found that the corrected absorbance of the carbonyl group corrected to the pressure of 1330 Pa (10 Torr) is 0.337, 0.656 and 1.050, respectively. From this result, it was confirmed that the FTIR has a sufficient sensitivity even at such low pressures and that it can be used for the monitoring of the concentration change of the W(CO)₆ gas by monitoring the change of the absorption peak intensity.

### EXAMPLE 2

In Example 2, W(CO)₆ is used for the source material and the source bottle 10 is held at 45° C. Further, an Ar gas was used for the carrier gas and the diluting gas. The FTIR 40 was provided at the upstream side of the processing vessel 100, similarly to the fourth embodiment, and the temperature of the source bottle was set to 45° C. Thereby, the carrier gas was supplied with the flow rate of 50 SCCM and the diluting gas was supplied with the flow rate of 10 SCCM.

In this experiment, a value of 0.235 was obtained initially for the absorbance of W(CO)₆ as corrected to the pressure of 1330 Pa (10 Torr) from the absorption peak of the carbonyl group.

After 5 minutes, it was found that the value of the absorbance has changed to 0.267, and thus, the flow rate of the diluting gas was increased slightly to the value of 12 SCCM. With this, it became possible to change the absorbance to 0.233, which is close to the original value.

### EXAMPLE 3

In Example 3, a tungsten film was formed by a pyrolytic CVD process while using W(CO)₆ as a source material.

In this experiment, the source bottle 10 was held at 60° C. and an Ar carrier gas was supplied with the flow rate of 300 SCCM. Further, an Ar diluting gas was supplied with the flow rate of 100 SCCM.

Further, in order to facilitate the vaporization of W(CO)₆, which provides only the vapor pressure of about 106 Pa at 60° C., and to increase the film-formation rate, the present embodiment activates the turbo molecular pump 14 and the dry pump 16 such that a process pressure of 0.15 Torr (about 20 Pa) is realized in the processing vessel body 120 and the pressure of 1.5 Torr (about 200 Pa) is realized in the source gas line 30.

As a result of the film formation conducted at the substrate temperature of 450° C., it was confirmed that there occurs a tungsten film formation with the rate of 7.1 nm/min. The tungsten film thus formed had the resistivity of 25 μΩcm.

[Fifth Embodiment]

As a result of various embodiments described heretofore, it became possible to maintain the concentration of the source gas supplied to the processing vessel body 120 constant after one process has been commenced, by using FTIR 40 and the controller 201.

On the other hand, the embodiments explained above do not measure the absolute concentration of the source gas, and because of this, there has been a need, in the event one process has been terminated and the supply of the source gas is interrupted, to seek for the optimum condition of film-formation upon commencement of the next film-formation process, by processing a number of test substrates so that the desired source gas concentration is attained. However, such a search of the optimum condition is time consuming and increases the cost of the produced semiconductor device.

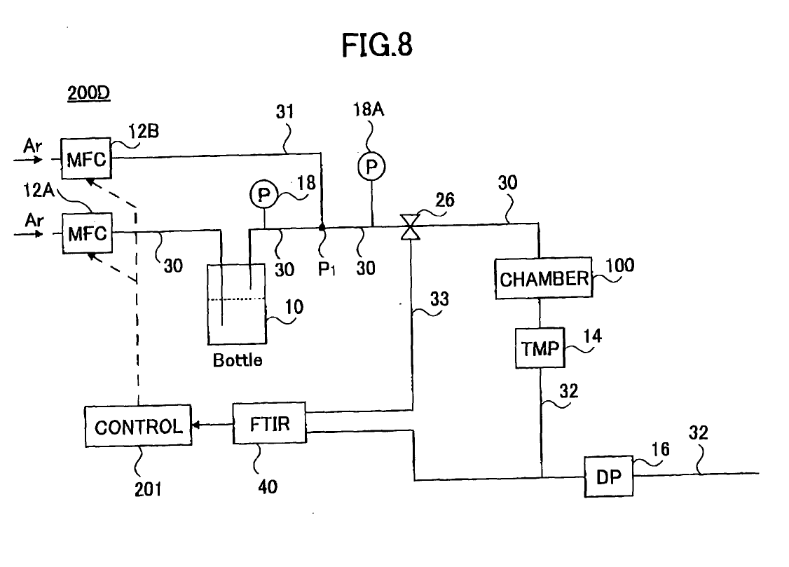

FIG. 8 shows the construction of an MOCVD apparatus 200D according to a fifth embodiment of the present invention that is capable of measuring the absolute source gas concentration by using the FTIR 40, wherein those parts described previously are designated by the same reference numerals and the description thereof will be omitted.

Referring to FIG. 8, the MOCVD apparatus 200D has a construction similar to the MOCVD apparatus 200A explained before, except that there is provided another manometer 18A at the downstream side of a node P1 where the diluting gas line 31 merges the source gas line 30 but at the upstream side of the processing vessel 100, for measuring the pressure of the mixed gas of the gas line 30 in the state that the Ar gas in the diluting gas line 31 is added to the gas in the source gas line 30.

The manometer 18A supplied the output signal corresponding to the detected pressure to the controller 201, and the controller 201 obtains the absolute concentration of the source gas in the mixed gas supplied to the processing vessel 100 via the source gas line 30 based on the output of the FTIR 40 and the output of the manometer 18A.

In the construction that supplies a source gas to the processing vessel 100 together with a carrier gas along the gas line 30, there holds a relationship

S=A×Ir×(1/P)×C (1)

wherein A is a constant depending on a cell length, S represents the flow rate of the source gas supplied to the processing vessel 100, Ir represents the absorption intensity of the source gas component in the mixed gas transported through the source gas line 30 obtained by the FTIR 40, P represents the pressure in the source gas line 30 connected to the processing vessel 100, and C represents the total flow rate of the carrier gas and the diluting gas in the gas line 30.

Thus, when the pressure P and the carrier/diluting gas total flow rate C are held constant and the source gas flow rate S is increased, there occurs an increase of the output signal Ir of the FTIR 40, while when the source gas flow rate S and the output Ir of the FTIR 40 are held constant and the pressure P is increased, there occurs an increase of the total gas flow rate C. Further, when the source gas flow rate increases with increase of the carrier/diluting gas total flow rate C even when the output Ir of the FTIR 40 and the pressure P are held constant.

The foregoing Equation (1) can be modified to

S/C=A×Ir×(1/P) (2)

wherein it should be noted that the left side term S/C is nothing but the absolute concentration of the source gas in the mixed gas introduced into the processing vessel 100.

Thus, Equation (2) means that it is possible to calculate the absolute concentration of the source gas in the mixed gas introduced into the processing vessel 100 when the measurement of the pressure P by the manometer 18A and the measurement of the absorbance Ir by the FTIR 40 are both conducted at the downstream side of the merging node P1, by using the absorbance Ir and the pressure P.

In the case of using an FTIR having a cell length of lm for the device 40, the measurement conducted under the atmospheric pressure (101.08 kPa) has yielded the data sets for the concentration S/C and the infrared absorption intensity Ir, or (S/C, Ir), of (0.314%, 1.19) and (0.043%, 0.21). From these data sets, the foregoing constant A is obtained as 26.9 (A=26.9) in the case the pressure is represented in terms of kilo Pascal.

Further, in the case of using an NDIR (non-dispersion type infrared spectrometer) to be described later, the data set for the pressure P and the absorption intensity Ir, or (P, Ir), of (0.04 kPa (=0.3 Torr), 0.0062) has been obtained for the NDIR having a cell length of 1 m, for the case the measurement is conducted under the carrier gas flow rate of 20 SCCM. In the case the measurement is conducted with the carrier gas flow rate of 500 SCCM, on the other hand, the data set of (0.20 kPa (=1.5 Torr), 0.0008) has been obtained. From these data sets, the source gas flow rate S is calculated as 0.88 SCCM and 0.56 SCCM, respectively, by using the constant A of 26.9 obtained before.

It should be noted that the value of the constant A depends on the cell length and becomes 1/10 in the case the cell length becomes ten times larger.

Thus, by using the absolute concentration in the step 302 of the flowchart of FIG. 6 for controlling the mass-flow controllers 12A and 12B by way of the controller 201, it becomes possible to control the absolute concentration of the source gas to the predetermined desired value. This means that it becomes possible to reproduce the optimum deposition condition with reliability even in the case a new film-formation process is restarted by supplying the source gas after termination of a previous film-formation process.

In Equation (2), the coefficient A is a constant pertinent to the apparatus. The coefficient A has the dimension of pressure and is determined experimentally.

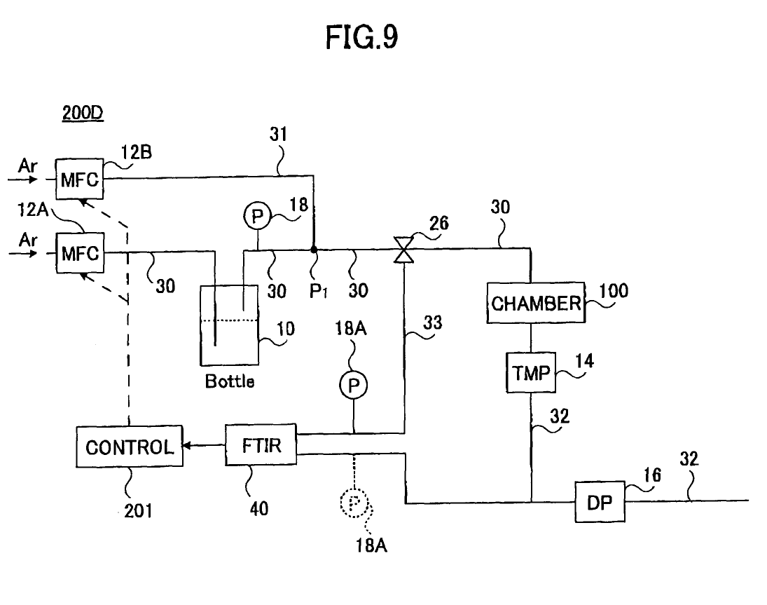

As it is sufficient in the present invention that the pressure of the mixed gas, which is subjected to the source concentration measurement, is determined, the location of the manometer 18A is not limited to the one shown in FIG. 8. Thus, it is also possible to provide the manometer 18A immediately before or after the FTIR 40 as represented in FIG. 9.

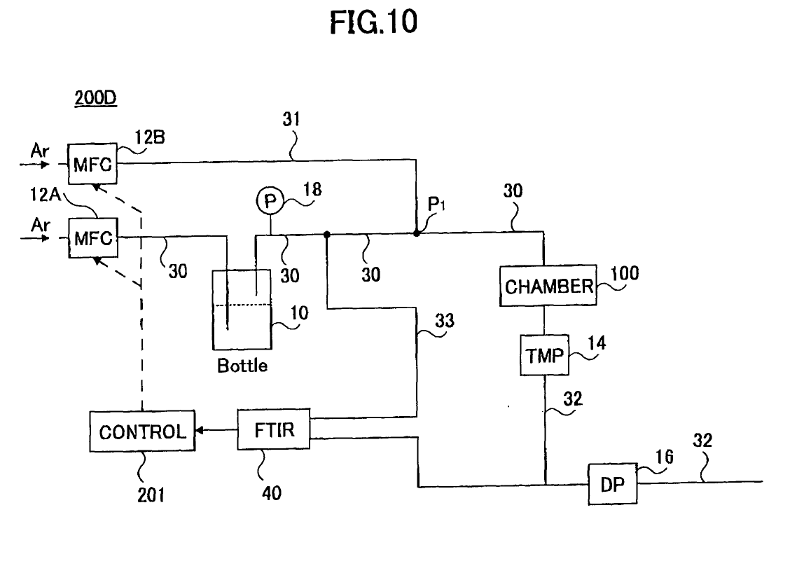

Further, because the FTIR 40 of the present embodiment can measure the absolute concentration of the source gas by using the FTIR 40, it is not mandatory to conduct the concentration measurement source gas at the downstream side of the node P1. Thus, it is also possible to conduct the pressure measurement at the upstream side of the node P1 as in the case of FIG. 10. In the construction of FIG. 10, it should be noted that the foregoing pressure measurement can be conducted by the manometer 18 provided on the gas line 30, and the use of additional manometer 18A is avoided.

[Modification]

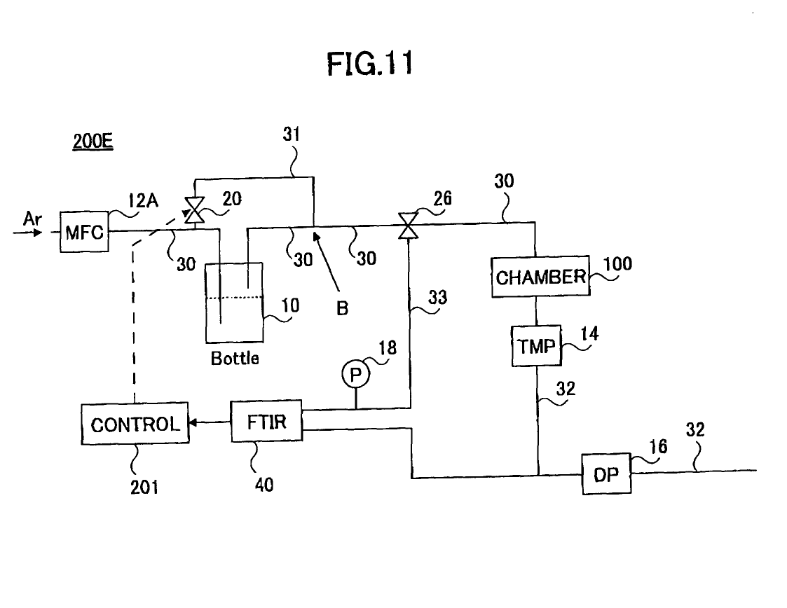

Similarly, it is possible to modify the MOCVD apparatus 200A of FIG. 3 by applying the manometer 18A as represented in an MOCVD apparatus 200E shown in FIG. 11. Thereby, it becomes possible to obtain the absolute concentration of the source gas in the source gas line 30. In FIG. 11, those parts corresponding to the parts described previously are designated by the same reference numerals and the description thereof will be omitted.

Further, modifications similar to those of FIGS. 9 and 10 are possible also in the MOCVD apparatus 200E of FIG. 11.

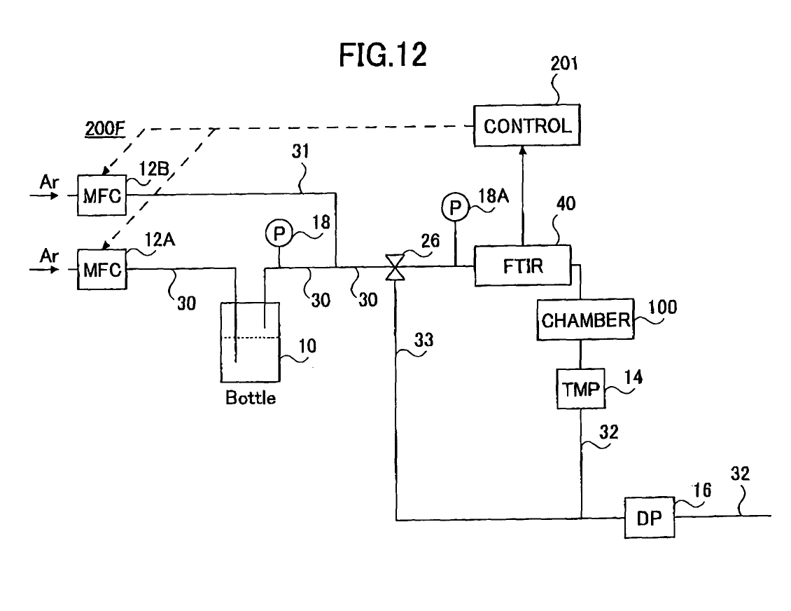

Further, it is possible to obtain the absolute source gas concentration in the source gas line 30 in the MOCVD apparatus 200B of FIG. 4 by adding the manometer 18F as represented in an MOCVD apparatus 200F of FIG. 12. In FIG. 12, those parts corresponding to the parts described previously are designated by the same reference numerals and the description thereof will be omitted.

It should be noted that the modification similar to those of FIGS. 9 and 10 is possible also in the MOCVD apparatus 200F of FIG. 12.

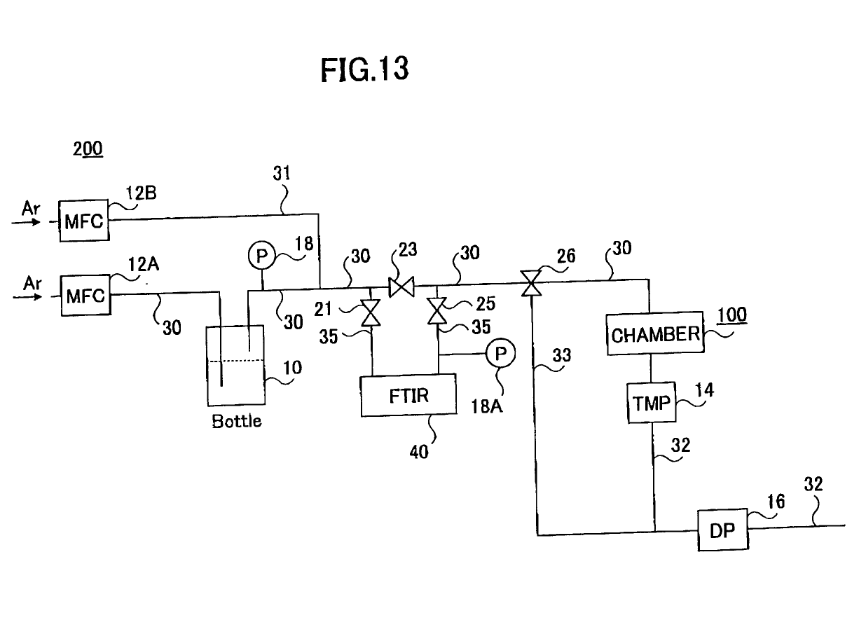

Further, as shown in an MOCVD apparatus 200G of FIG. 13, it becomes possible to obtain the absolute source gas concentration in the source gas line 30 by adding the manometer 18A to the MOCVD apparatus 200C of FIG. 4. In FIG. 13, those parts corresponding to the parts described previously are designated by the same reference numerals and the description thereof will be omitted.

In the MOCVD apparatus 200G of FIG. 13, too, similar modifications as in the case of FIGS. 9 and 10 are possible.

[Sixth Embodiment]

FIG. 14 shows the construction of the FTIR 40 used in various embodiments of the present invention.

Referring to FIG. 14, the FTIR 40 includes a gas passage 401 having optical windows 401A and 401B, and mirrors 401a-401c are provided in the gas passage 401 for reflecting an optical beam incident through the optical window 401A one after another. The optical beam thus reflected exits through the optical window 401B, and there is provided a detector 402 for detecting the optical thus exit from the optical window 401B.

Further, there is provided an interferometer 403 including therein a fixed mirror 403a, a movable mirror 403b and a semitransparent mirror 403c outside the optical window 401A, wherein the interferometer 403 introduces the optical beam from an infrared source 404 into the gas passage through he optical window 401A.

The detector 402 supplies an output signal to an A/D converter 402A for conversion to a digital signal, and the digital signal thus converted undergoes high-speed Fourier transform in a computer 402B. Thereby, the spectrum of the gas passing through the gas passage 401 is calculated as shown in FIG. 7.

In the FTIR 40 of FIG. 14, it should be noted that baseline length of the interferometer 403 is changed by moving the foregoing movable mirror 403b while simultaneously detecting the intensity of the incoming infrared optical beam at the detector 402. By applying the high-speed Fourier transform to the interference pattern thus acquired in the computer 402B, the infrared spectrum of the source gas is calculated.

In the present embodiment, it should be noted that the mirrors 401a and 401c are held on a base body 401C and the mirror 401b is held on a base body 401D. Thereby, a temperature sensor 401CT such as a thermocouple and heaters 401CB, 401CD are provided in the base body 401C. Similarly, a temperature sensor 401DT such as a thermocouple and a heater 401DB are provided in the base body 401D. In addition, while the illustration is omitted, the optical windows 401A and 401B are also provided with a temperature sensor and a heater.

Because the mirrors that make direct contact with the gas flow are maintained at a predetermined temperature in the present embodiment, the problem of formation of precipitates, which is caused when the source gas undergoes cooling upon passing through the FTIR 40, is positively avoided. It should be noted that the source gas of W(CO)₆ has to be maintained at a high temperature during the transportation for avoiding formation of such precipitates.

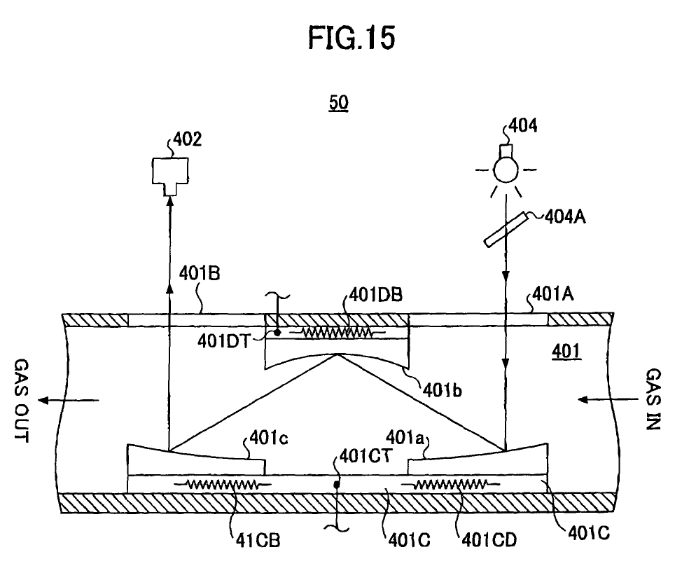

In each of the foregoing various embodiments, it is also possible to use a non-dispersion infrared spectrometer (NDIR) 50 shown in FIG. 15 in place of the FTIR 40. Thereby, it becomes possible to obtain an output signal within the duration of 1 second. In FIG. 15, those parts described previously are designated by the same reference numerals and the description thereof will be omitted.

It should be noted that the NDIR 50 has a construction similar to that of the FTIR 40 except that the interferometer 403 and the computer 402B for carrying out the high-speed Fourier transform are omitted. Further, a chopper 404A is provided in the optical path of the infrared beam emitted from the optical source 404 for interrupting the infrared beam intermittently. It should be noted that the chopper 404A may be provided at any location of the optical path of the infrared beam traveling from the optical source 404 to the detector 402.

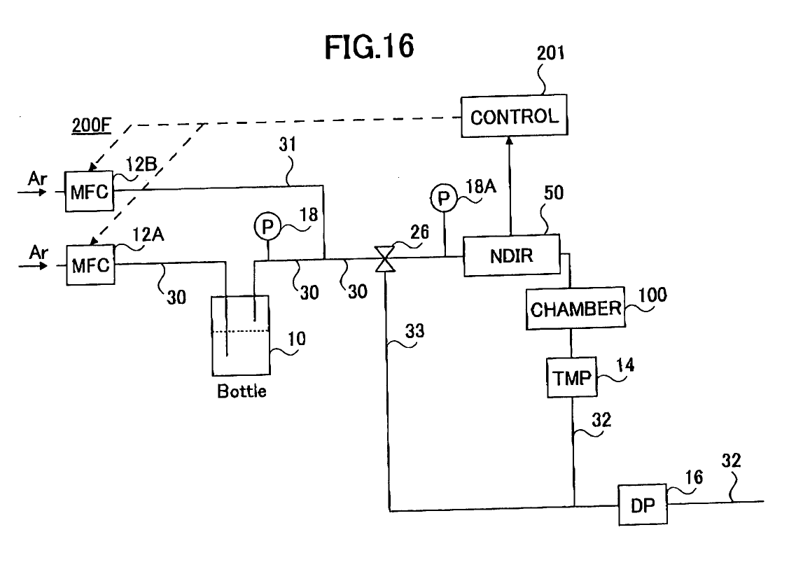

In the NDIR 50 of FIG. 15, too, the mirrors 401a-401c contacting with the gas flow directly are maintained at the predetermined temperature, and the problem of formation of the precipitates is avoided. The NDIR 50 of FIG. 15 may be used in place of the FTIR 40 in the construction of FIG. 12 as represented in FIG. 16. It should be noted that similar modification is possible also in other embodiments.

Further, the present invention is not limited to the embodiments described heretofore, but various variations and medications may be made without departing from the scope of the invention.

For example, it is possible to provide a turbo molecular pump in the pre-flow line 33 in correspondence to the film-formation process that uses a low vapor pressure source material. Further, the diameter of the pre-flow line 33 may be optimized. According to such a construction, it becomes possible to measure the source gas concentration under the condition close to the case of the source gas is actually transported along the source gas line 30 for the film-formation process by using the FTIR 40 provided in the pre-flow line 33.

Further, it is also possible to conduct the detection of the source gas concentration by other means than the FTIR measurement or the measurement of the infrared spectrum. In the case the processing is conducted under a sufficiently high process pressure, it is possible to use the acoustic emission method in view of the relatively high pressure of the source gas. In this case, too, it is possible to calculate the absolute source gas concentration by applying a pressure correction according to Equation (2).

The present invention is based on Japanese priority application 2002-201532 and 2003-191044 filed respectively on Jul. 10, 2002 and Jul. 3, 2003, the entire contents thereof being incorporated herein as reference.

What is claimed is:

1. A film-formation apparatus, comprising:
a film-formation chamber; and
a source gas supplying apparatus supplying a source gas to said film-formation chamber together with a carrier gas,
said source gas supplying apparatus comprising:
a concentration detector detecting a concentration of said source gas; and
a gas flow controller controlling a flow rate of an inert gas added to said carrier gas based on a result of measurement of said concentration of said source gas obtained by said concentration detector.

2. A film-formation apparatus as claimed in claim 1, wherein said inert gas is added to said carrier gas that is carrying said source gas.

3. A film-formation apparatus as claimed in claim 1, wherein said concentration detector is provided so as to measure said concentration of said source gas in the state said inert gas is added to said carrier gas.

4. A film-formation apparatus as claimed in claim 1, wherein said gas flow controller changes said flow rate of said inert gas added to said carrier gas such that said concentration of said source gas as measured by said concentration detector falls in a predetermined concentration range.

5. A film-formation apparatus as claimed in claim 1, wherein said concentration detector measures said concentration of said source gas before commencement of a film-formation process and/or during said film-formation process.

6. A film-formation apparatus as claimed in claim 1, wherein said source gas supplying apparatus further includes a switching device switching a flow path of said carrier gas added with said inert gas, between a first path connected to said film-formation chamber and a second path bypassing said film-formation chamber, said concentration detector being provided in one of said first and second flow paths.

7. A film-formation apparatus as claimed in claim 1, wherein said gas flow controller changes a flow rate of said inert gas to be added to said carrier gas, and wherein said gas flow controller further changes a flow rate of said carrier gas such that a total flow rate of said carrier gas and said inert gas is maintained generally constant.

8. A film-formation apparatus as claimed in claim 1, wherein said carrier gas and said inert gas are introduced from an identical flow path, said inert gas being then diverted to another flow path before said carrier gas is admixed with said source gas, said inert gas merging again with said flow path of said carrier gas after said carrier gas is admixed with said inert gas.

9. A film-formation apparatus as claimed in claim 1, wherein said gas flow controller controls a flow rate of said inert gas in said another flow path.

10. A film-formation apparatus as claimed in claim 1, wherein said source gas is formed by vaporizing a source material of which vapor pressure less than 266 Pa at a temperature at which said source material is used.

11. A film-formation apparatus as claimed in claim 1, wherein said source gas is W(CO)₆.

12. A film-formation apparatus as claimed in claim 1, wherein said concentration detector is a Fourier transform infrared spectrometer.

13. A source supplying system of a film-formation apparatus, comprising:
a concentration detector detecting a concentration of said source gas; and
a gas flow controller controlling a flow rate of an inert gas added to said carrier gas based on a result of measurement of said concentration of said source gas obtained by said concentration detector.

14. A film-formation apparatus, comprising:
a film-formation chamber; and
a source gas supplying apparatus supplying a source gas to said film-formation chamber together with a carrier gas via a gas passage in the form of a mixed gas,
said source supplying apparatus comprising:
a gas concentration measurement part measuring the concentration of said source gas contained in said mixed gas in said gas passage;
a gas concentration controller connected to said gas passage, said gas concentration controller adding an inert gas to said mixed gas in said gas passage; and
an inert-gas flow-rate controller controlling the flow rate of said inert gas added by said gas concentration controller based on a measured concentration of said source gas obtained by said gas concentration measurement part,
said gas concentration measurement part including a manometer for measuring the pressure of said mixed gas in said gas passage, said gas concentration measurement part correcting said measured concentration of said source gas based on a pressure measured by said manometer.

15. A film-formation apparatus as claimed in claim 14, wherein said gas concentration measurement part includes a gas concentration detector that supplies a probe signal to said mixed gas in said gas passage, said gas concentration detector producing a detection signal corresponding to said concentration of said source gas based upon said probe signal passed through said mixed gas,
said gas concentration measurement part further including a signal processing unit correcting said signal obtained by said gas concentration detector by said pressure and calculating an absolute concentration of said source gas in said mixed gas from said signal corrected by said pressure.

16. A film-formation apparatus as claimed in claim 15, wherein said signal processing unit multiplies a correction term, which includes said pressure of said mixed gas at a denominator, to a value of said signal detected by said gas concentration detector.

17. A film-formation apparatus as claimed in claim 15, wherein said manometer is provided at any of an upstream side and a downstream side of said gas concentration detector.

18. A film-formation apparatus s claimed in claim 14, wherein said concentration measurement part measures said concentration of said source gas in said gas passage at a downstream side of a location where said inert gas is admixed to said mixed gas.

19. A film-formation apparatus as claimed in claim 14, wherein said concentration measurement part measures said concentration of said source gas in said gas passage at an upstream side of a location where said inert gas is added to said mixed gas.

20. A film-formation apparatus as claimed in claim 15, wherein said gas concentration detector injects infrared light to said mixed gas and produces said signal based upon an infrared absorption spectrum of said infrared light passed through said mixed gas.

21. A film-formation apparatus as claimed in claim 15, wherein said gas concentration detector comprises a Fourier transform infrared spectrometer.

22. A film-formation apparatus as claimed in claim 14, wherein said gas concentration detector comprises a non-dispersion infrared spectrometer.

23. A film-formation apparatus as claimed in claim 20, wherein said gas concentration detector comprises a mirror disposed in said gas passage and a heating element heating said mirror.

24. A film-formation apparatus as claimed in claim 14, wherein said mixed gas has a pressure of 1.33 kPa or less in said gas passage.

25. A method of detecting a gas concentration, comprising the steps of:
supplying a mixed gas containing therein a source gas to a flow passage;
measuring the pressure of said mixed gas in said flow passage;
injecting infrared light to said mixed gas in said flow passage;
acquiring an absorption spectrum of said source gas by detecting said infrared light after said infrared light has passed through said mixed gas in said flow passage;
acquiring the concentration of said source gas in said mixed gas by correcting an intensity of said absorption spectrum, said step of correction comprising the step of applying a correction term including therein said pressure.

26. A method as claimed in claim 25, wherein said correction term includes a term of said pressure at a denominator.

27. A method as claimed in claim 25, wherein said step of injecting said infrared light is conducted by using an interferometer capable of changing a baseline length and by changing said baseline length.

28. A method as claimed in claim 25, wherein said step of acquiring said absorption spectrum includes fast Fourier-transform processing.

29. A method as claimed in claim 25, wherein any of said step of injecting said infrared light and said step of detecting said infrared light includes the step of interrupting said infrared light intermittently at an upstream side, in an optical path of said infrared light, of a detector used for detecting said infrared light.
